(19) United States
(12) Patent Application Publication
(10) Pub. No.: US 2012/0049866 A1
(43) Pub. Date: Mar. 1, 2012

(54) METHOD AND DEVICE FOR MEASURING PRESSURE-BASED INDUCTANCE OF ELECTROMAGNETIC TABLET

(76) Inventor: Songlin Wu, Beijing (CN)

(21) Appl. No.: 13/318,686

(22) PCT Filed: Sep. 7, 2009
(86) PCT No.: PCT/CN2009/073784

§ 371 Date: Nov. 3, 2011

(30) Foreign Application Priority Data
May 25, 2009 (CN) 200910085535.2

(51) Int. Cl. G01R 27/28

(52) U.S. Cl. 324/655

(57) ABSTRACT

The invention relates to a method and a device for measuring pressure-based inductance of an electromagnetic tablet, which relates to the field of computer peripheral input device. The method comprises steps of: measuring a first parameter value when an electromagnetic pen is not operating; measuring a second parameter value when the electromagnetic pen is operating, and inductance value of inductor in a resonance circuit varies with pressure; and calculating the pressure-based inductance based on the first and second parameter values. The device comprises: a resonance circuit comprising an inductor whose inductance value varies with pressure when an electromagnetic pen is operating; a measurement circuit configured to measure a first parameter value when the electromagnetic pen is not operating, to measure a second parameter value when the electromagnetic pen is operating, and to calculate the is pressure-based inductance based on the first and second parameter values, the difference between the second parameter value and the first parameter value being associated with variation of the inductance value. According to the present invention, the pressure-based inductance can be calculated based on the measured first and second parameter values that vary with the inductance, and difficulty and cost for measuring the pressure-based inductance are reduced.

### FIELD OF THE INVENTION

The invention relates to the field of computer peripheral input device, and more particularly, to a method and a device for measuring pressure-based inductance of an electromagnetic tablet.

### BACKGROUND OF THE INVENTION

An electromagnetic tablet is a common peripheral device of a computer which is used together with an electromagnetic pen. Data including coordinates of track and magnitude of pressure produced by the electromagnetic pen moving on the electromagnetic tablet, inclination angle of the electromagnetic tablet and the like is transmitted to the computer via the electromagnetic tablet, thereby a picture is drawn. Thickness of the track of the electromagnetic pen drawn on the electromagnetic tablet is controlled by a force generated by the electromagnetic pen contacting the electromagnetic tablet, i.e., pressure-based inductance measured by the electromagnetic tablet.

There are two methods for measuring pressure-based inductance in a conventional wireless passive electromagnetic inductive electromagnetic tablet. The first one is based on variation of phase of a waveform of a received signal due to variation of inductance in the pen. This method has a disadvantage of requirement for post software processing because the pressure-based inductance does not vary with the pressure in a smooth way, and thus it is difficult to control and to measure the pressure-based inductance. The second one is to perform measurement by means of a circuit composed of an RC circuit, a comparator and a timer. A variable capacitor whose capacitance varies with pressure is needed in the method, which imposes a higher demand to the manufacturing process for the variable capacitor and results in a higher cost for the measurement of the pressure-based inductance.

### SUMMARY OF THE INVENTION

In view of the disadvantages of the prior art, an object of the present invention is to provide a method and a device for measuring pressure-based inductance of an electromagnetic tablet, and an electromagnetic pen, to reduce difficulty and cost for measuring the pressure-based inductance.

In order to achieve the above object, there is provided a method for measuring pressure-based inductance of an electromagnetic tablet, comprising steps of:
measuring a first parameter value when an electromagnetic pen is not operating;
measuring a second parameter value when the electromagnetic pen is operating and an inductance value of an inductor in a resonance circuit varies with pressure, the difference between the second parameter value and the first parameter value being associated with a variation of the inductance value; and
calculating the pressure-based inductance based on the first and second parameter values.

Preferably, the method further comprises steps of: applying a high level on a terminal of a resistor of the resonance circuit; comparing a reference level with a level at a node between the resistor and the inductor in the resonance circuit, and outputting a comparison level; and controlling a timer to start or stop timing based on the comparison level, a pulse width recorded by the timer being the parameter value.

Preferably, the method further comprises steps of: controlling the timer to start timing when the output comparison level is low; controlling the timer to stop timing when the output comparison level is high, wherein the pulse width recorded when the electromagnetic pen is not operating is the first parameter value, while the pulse width recorded when the electromagnetic pen is operating is the second parameter value.

In order to achieve the above object, there is further provided a device for measuring pressure-based inductance of an electromagnetic tablet, comprising: a resonance circuit comprising an inductor whose inductance value varies with pressure when an electromagnetic pen is operating; a measurement circuit configured to measure a first parameter value when the electromagnetic pen is not operating, and to measure a second parameter value when the electromagnetic pen is operating, and to calculate the pressure-based inductance based on the first and second parameter values, the difference between the second parameter value and the first parameter value being associated with variation of the inductance value.

Preferably, the inductor in the resonance circuit comprises a fixed inductor comprised of a first magnetic core and an enameled wire winding around the first magnetic core, and a second magnetic core that varies the inductance with the pressure by moving with respect to the first magnetic core.

Preferably, the second magnetic core is placed in the first magnetic core. The pressure is applied on the second magnetic core to move the second magnetic core when the electromagnetic pen is operating on the electromagnetic tablet, thereby the inductance value of the resonance circuit varies with the pressure.

Preferably, the measurement circuit comprises a controller, a comparator and a timer, wherein: a terminal of a resistor of the resonance circuit is connected to the controller; the input terminals of the comparator are coupled to a reference level and a level at a node between the resistor and the inductor in the resonance circuit, respectively; an output terminal of the comparator is connected to the controller; and the controller controls the timer to start or stop timing based on a level at the output terminal of the comparator.

Preferably, the controller is further configured to apply a high level on a terminal of the resistor of the resonance circuit, to control the timer to start timing when the level at the output terminal of the comparator is low, and to control the timer to stop timing when the level at the output terminal of the comparator is high, wherein the pulse width recorded when the electromagnetic pen is not operating is the first parameter value, while the pulse width recorded when the electromagnetic pen is operating is the second parameter value.

In order to achieve the above object, there is further provided an electromagnetic pen comprising the device for measuring pressure-based inductance of an electromagnetic tablet as above.

According to the present invention, because the inductance in the resonance circuit varies with the pressure, a first parameter value when the electromagnetic pen is not operating and a second parameter value when the electromagnetic pen is operating are measured, and thus the pressure-based inductance can be calculated based on the first and second parameter values. There is no need for additional processing and components of complex techniques, thereby the difficulty and cost for measuring the pressure-based inductance are reduced.

### BRIEF DESCRIPTION OF THE DRAWINGS

FIG. 1 is a schematic flowchart illustrating a method for measuring pressure-based inductance of an electromagnetic tablet according to the present invention;

FIG. 2 is a schematic block diagram of a device for measuring pressure-based inductance of an electromagnetic tablet according to the present invention;

FIG. 3 is a schematic circuit diagram of a device for measuring pressure-based inductance of an electromagnetic tablet according to the present invention;

FIG. 4(a) illustratively shows a waveform of a level applied at a terminal A of a resistor R;

FIG. 4(b) illustratively shows a waveform of an output voltage at a terminal B of a resistor R when the electromagnetic pen is not operating;

FIG. 4(c) illustratively shows a waveform of an output voltage at an output terminal C of a comparator when the electromagnetic pen is not operating;

FIG. 4(d) illustratively shows a waveform of an output voltage at a terminal B of a resistor R when the electromagnetic pen is operating;

FIG. 4(e) illustratively shows a waveform of an output voltage at an output terminal C of a comparator when the electromagnetic pen is operating; and

FIG. 5 is a schematic diagram of an inductor that is applicable in a resonance circuit according to the present invention.

### DETAILED DESCRIPTION OF PREFERRED EMBODIMENTS

In the following, the present invention will be described in detail with reference to the figures.

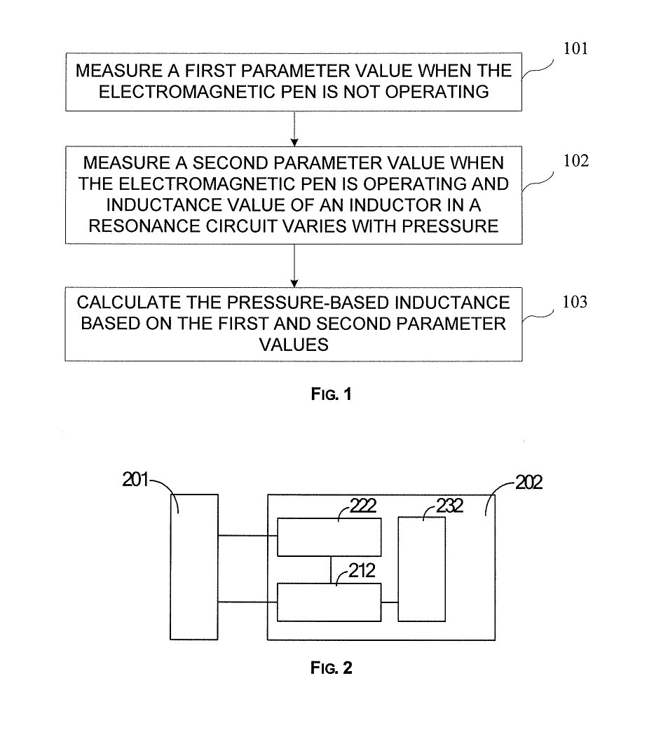

FIG. 1 is a schematic flowchart illustrating a method for measuring pressure-based inductance of an electromagnetic tablet according to the present invention. As shown in FIG. 1, the method for measuring pressure-based inductance of an electromagnetic tablet according to the present invention comprises:

Step 101: measuring a first parameter value when an electromagnetic pen is not operating.

Specifically, step 101 may comprise steps of applying a high level on a terminal of a resistor of a resonance circuit; comparing a reference level with a level at a node between the resistor and an inductor in the resonance circuit, and outputting a comparison level; controlling a timer to start or stop timing based on the comparison level output from the comparator, and recording a pulse width as a first parameter value.

Step 102: measuring a second parameter value when the electromagnetic pen is operating and inductance value of a resonance circuit varies with pressure, a difference between the second parameter value and the first parameter value being associated with variation of the inductance value.

Specifically, step 102 may comprise steps of applying a high level on a terminal of the resistor of the resonance circuit; comparing the reference level with a level output from the resonance circuit, and outputting a comparison level; controlling the timer to start or stop timing based on the comparison level output from the comparator, and recording a pulse width as a second parameter value.

The timer may be controlled to start timing when the comparison level is low, and stop timing when the comparison level is high.

Step 103, calculating the pressure-based inductance based on the first and second parameter values.

The pressure-based inductance may be calculated based on correspondence between the pressure-based inductance and the difference between the first and second parameter values.

FIG. 2 is a schematic block diagram of a device for measuring pressure-based inductance of an electromagnetic tablet according to the present invention. As shown in FIG. 2, the device comprises a resonance circuit 201 and a measurement circuit 202. The resonance circuit 201 is an RL circuit whose inductance varies with the pressure between the electromagnetic pen and the electromagnetic tablet variations. The measurement circuit 202 measures a first parameter value when the electromagnetic pen is not operating on the electromagnetic tablet, measures a second parameter value when the electromagnetic pen is operating on the electromagnetic tablet, and calculates the pressure-based inductance based on the first and second parameter values.

The measurement circuit 202 comprises a controller 212, a comparator 222 and a timer 232. The controller 212 and the comparator 222 are connected to the resonance circuit 201. The comparator 222 has its input terminals coupled to a reference level and a level of the resonance circuit, respectively, and an output terminal connected to the controller 212. The timer 232 is controlled by the controller 212 to start or stop timing based on a level at the output terminal of the comparator 222. The controller 212 applies a high level on the resonance circuit 201, controls the timer 232 to start timing when the level at the output terminal of the comparator 222 is low, and controls the timer 232 to stop timing when the level at the output terminal of the comparator 222 is high, and records a pulse width as the parameter value. Herein, the level at the output terminal of the comparator is the result of comparing the reference level with the level at a node between the resistor and the inductor in the resonance circuit.

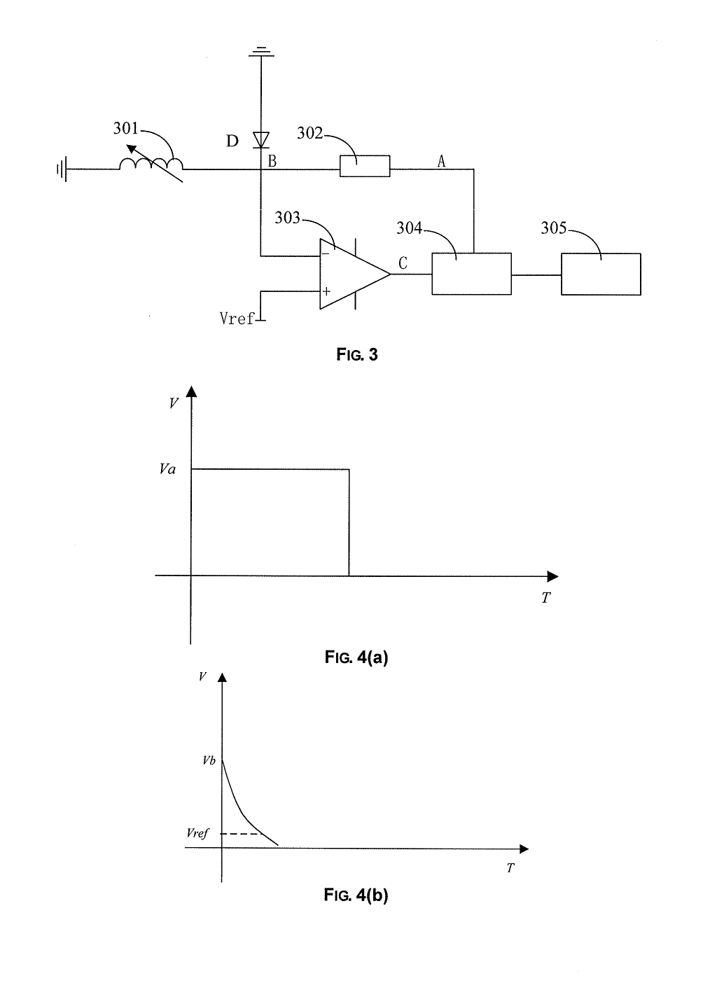

FIG. 3 is a schematic circuit diagram of a device for measuring pressure-based inductance of an electromagnetic tablet according to the present invention. As shown in FIG. 3, a terminal A of a resistor 302 is connected to an I/O terminal of a controller 304. An inductor 301 and a terminal B of the resistor 302 are connected to an inverse input terminal of the comparator 303. The inductor 301 and a reference voltage Vref are coupled to a non-inverse input terminal of the comparator 303. The comparator 303 outputs at an output terminal C a result of comparison between the reference voltage Vref with the voltage output at terminal B of the resistor 302. The inverse input terminal of the comparator 303 is also connected with a diode D for preventing occurrence of a negative voltage so as to protect the comparator 303.

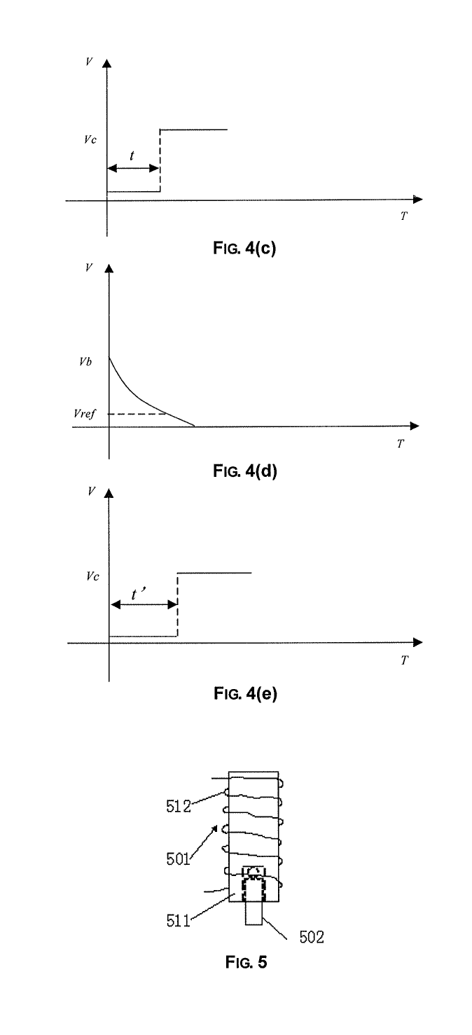

The controller applies a high level as shown in FIG. 4(a) at the terminal A of the resistor R when the electromagnetic pen does not contact the electromagnetic tablet but is within an inductive range of the electromagnetic tablet. The waveform of the output voltage at the terminal B of the resistor R varies over time as shown by Vb in FIG. 4(b). The waveform of the output voltage at the output terminal C of the comparator varies over time as shown by Vc in FIG. 4(c). The controller controls the timer to start timing when the voltage at the output terminal C of the comparator is low and stop timing when the voltage at the output terminal C of the comparator is high. The pulse width t so recorded is an initial value corresponding to a zero pressure.

The inductance L becomes larger due to the force between the electromagnetic pen and the electromagnetic tablet when the electromagnetic pen contacts and operates on the electromagnetic tablet. The voltage at the terminal B of the resistor R damps in a reduced rate, as shown in FIG. 4(d) where the curve representing the voltage at the terminal B of the resistor R descends more slowly, rendering the negative pulse at the output terminal C of the comparator wider as compared with the one shown in FIG. 4(c). The timer starts timing when the voltage at the output terminal C of the comparator is low and stops timing when the voltage at output terminal C of the comparator is high. The pulse width recorded during this period is as shown by t′ in FIG. 4(e). The pressure-based inductance of the electromagnetic tablet is calculated by calculating the difference t′−t and based on the correspondence between the difference and the pressure-based inductance.

FIG. 5 is a schematic diagram of an inductor that is applicable in a resonance circuit according to the present invention. As shown in FIG. 5, the inductor in a resonance circuit according to the present invention comprises a fixed inductor 501 and a second magnetic core 502. The fixed inductor 501 comprises a first magnetic core 511 and an enameled wire 512 winding around the first magnetic core 511. The second magnetic core 502 varies the inductance of the resonance circuit according to pressure. Specifically, the first magnetic core 511 has a cavity along its central axis direction. An elastic ball is placed at the bottom of the cavity. The second magnetic core 502 is placed within the cavity by means of the elastic ball. When the electromagnetic pen operates on the electromagnetic tablet, a pressure is applied vertically on the second magnetic core 502, and the second magnetic core 502 moves inward in the central axis direction of the first magnetic core 511. The inductance L of the resonance circuit becomes larger, the voltage at the terminal B of the resistor R damps more slowly, and the pulse becomes wider. When the pressure reduces, the second magnetic core 502 moves outward in the central axis direction of the first magnetic core 511. The inductance L of the resonance circuit becomes smaller, the voltage at the terminal B of the resistor R damps faster, and the pulse becomes narrower.

The device for measuring pressure-based inductance of an electromagnetic tablet according to the present invention can be arranged entirely in the electromagnetic pen to form an electromagnetic pen capable of measuring pressure-based inductance of an electromagnetic tablet.

According to the present invention, the inductance in the resonance circuit varies with the pressure, a first parameter value when the electromagnetic pen is not operating and a second parameter value when the electromagnetic pen is operating are measured, and thus the pressure-based inductance can be calculated based on the first and second parameter values. There is no need for additional processing and components of complex techniques, thereby the difficulty and cost for measuring the pressure-based inductance are reduced.

A particular circuit is provided herein for illustrating the present application. Those skilled in the art will appreciate that a circuit of different structures is also applicable. For example, the comparator has its output terminal connected to the timer without via the controller. The measurement of the pressure-based inductance can also be achieved by a circuit of such a structure. Those skilled in the art will appreciate to use other parameter values to measure the pressure-based inductance as long as there is correspondence between the parameter values and the inductance that varies with the pressure.

Of course, a number of variants and modifications can be made by those skilled in the art without departing from the spirit and scope of the present invention. All variants and modifications of the present invention coming within the meaning and equivalency range of the appended claims are intended to be embraced therein.

1. A method for measuring pressure-based inductance of an electromagnetic tablet, comprising steps of:
measuring a first parameter value when an electromagnetic pen is not operating;
measuring a second parameter value when the electromagnetic pen is operating and inductance value of an inductor of a resonance circuit varying with pressure, a difference between the second parameter value and the first parameter value being associated with variation of the inductance value; and
calculating the pressure-based inductance based on the first and second parameter values.

2. The method according to claim 1, further comprising steps of:
applying a high level on a terminal of a resistor of the resonance circuit;
comparing a reference level with a level at a node between the resistor and the inductor in the resonance circuit, and outputting a comparison level; and
controlling a timer to start or stop timing based on the comparison level, a pulse width recorded by the timer being the parameter value.

3. The method according to claim 2, further comprising steps of:
controlling the timer to start timing when the comparison level being output is low;
controlling the timer to stop timing when the comparison level being output is high,
wherein the pulse width recorded when the electromagnetic pen is not operating is the first parameter value, while the pulse width recorded when the electromagnetic pen is operating is the second parameter value.

4. A device for measuring pressure-based inductance of an electromagnetic tablet, comprising:
a resonance circuit comprising an inductor whose inductance value varies with pressure when an electromagnetic pen is operating;
a measurement circuit configured to measure a first parameter value when the electromagnetic pen is not operating, to measure a second parameter value when the electromagnetic pen is operating, and to calculate the pressure-based inductance based on the first and second parameter values, a difference between the second parameter value and the first parameter value being associated with variation of the inductance value.

5. The device according to claim 4, wherein the inductor of the resonance circuit comprises:
a fixed inductor comprised of a first magnetic core and an enameled wire winding around the first magnetic core, and a second magnetic core that varies the inductance with the pressure by moving with respect to the fixed inductor.

6. The device according to claim 5, wherein the second magnetic core is placed in the fixed inductor; the pressure is applied on the second magnetic core to move the second magnetic core when the electromagnetic pen is operating on the electromagnetic tablet, thereby the inductance of the fixed inductor varies with the pressure.

7. The device according to claim 4, wherein the measurement circuit comprises a controller, a comparator and a timer, wherein a terminal of a resistor of the resonance circuit is connected to the controller, input terminals of the comparator are coupled to a reference level and a level at a node between the resistor and the inductor in the resonance circuit, respectively, an output terminal of the comparator is connected to the controller, and the controller is configured to control the timer to start or stop timing based on a level at the output terminal of the comparator.

8. The device according to claim 7, wherein the controller is further configured to apply a high level on a terminal of the resistor of the resonance circuit, to control the timer to start timing when the level at the output terminal of the comparator is low, and to control the timer to stop timing when the level at the output terminal of the comparator is high, wherein the pulse width recorded when the electromagnetic pen is not operating is the first parameter value, while the pulse width recorded when the electromagnetic pen is operating is the second parameter value.

9. An electromagnetic pen comprising the device of claim 4.

10. An electromagnetic pen comprising the device of claim 5.

11. An electromagnetic pen comprising the device of claim 6.

12. An electromagnetic pen comprising the device of claim 7.

13. An electromagnetic pen comprising the device of claim 8.
